(19) United States
(12) Patent Application Publication
(10) Pub. No.: US 2006/0051615 A1
(43) Pub. Date: Mar. 9, 2006

(54) Organic electroluminescent element

(76) Inventors: Hiroshi Kanno, Osaka-city (JP); Kenji Okumoto, Hirakata-city (JP); Yuji Hamada, Ikoma-gun (JP); Haruhisa Hashimoto, Toyonaka-city (JP); Masahiro Iyori, Hirakata-city (JP); Kazuki Nishimura, Hirakata-city (JP)

Correspondence Address: MCDERMOTT WILL & EMERY LLP, 600 13TH STREET, N.W., WASHINGTON, DC, 20005-3096, US

(21) Appl. No.: 11/085,268

(22) Filed: Mar. 22, 2005

(30) Foreign Application Priority Data
Mar. 25, 2004 (JP) 2004-89207
Mar. 25, 2004 (JP) 2004-89209
Dec. 27, 2004 (JP) 2004-375901

(51) Int. Cl. H05B 33/12

(52) U.S. Cl. 428/690; 428/917; 428/212; 313/504; 313/506

(57) ABSTRACT

In an organic electroluminescent element in which a light emitting layer is disposed between a hole injection electrode and an electron injection electrode, and a hole injection layer is provided between the hole injection electrode and the light emitting layer, and an electron transport layer is provided between the electron injection electrode and the light emitting layer, the organic electroluminescent element is characterized in that a fluorocarbon layer is provided between the hole injection layer and the light emitting layer, and the electron transport layer is formed from a phenanthroline compound.

The priority Japanese Patent Application Numbers 2004-89207, 2004-89209 and 2004-375901 upon which this patent application is based is hereby incorporated by reference.

### BACKGROUND OF THE INVENTION

1. Field of the Invention

The present invention relates to an organic electroluminescent element.

2. Description of the Related Art

An organic electroluminescent element (organic EL element) has actively been developed from the viewpoint of the application to displays and illumination. The driving principle of an organic EL element is as follows. That is, holes and electrons are injected from a hole injection electrode and an electron injection electrode respectively, transported in an organic thin film and recombined in a light emitting layer to cause an excited state, from which luminescence is obtained.

With regard to an organic EL element, holes and electrons are transported in an organic thin film as described above, and an electron transport layer made of electron transporting materials is occasionally provided between an electron injection electrode and a light emitting layer. Alq (tris-(8-quinolinate)aluminum(III)) has been known as a typical compound of electron transporting materials and widely employed as an electron transport layer of an organic EL element (Japanese Unexamined Patent Publications No. 8-185984 and 2000-260572).

However, with regard to a conventional organic EL element in which Alq is employed for an electron transport layer, the problem is that holes become so excessive in a light emitting layer as to deteriorate the balance of holes and electrons therein and be incapable of raising luminous efficiency. Also on the occasion of injecting holes from a hole injection electrode, the problem is that an injection barrier thereto is so large as to raise driving voltage.

### SUMMARY OF THE INVENTION

A first object of the present invention is to provide an organic EL element such that an amelioration in the balance of electrons and holes in a light emitting layer allows driving voltage to be reduced and luminous efficiency to be improved.

A second object of the present invention is to provide an organic EL element such that the control of electron injection quantity into a light emitting layer improves life properties.

A first aspect of the present invention is an organic EL element in which a light emitting layer is disposed between a hole injection electrode and an electron injection electrode, and a hole injection layer is provided between the hole injection electrode and the light emitting layer, and an electron transport layer is provided between the electron injection electrode and the light emitting layer, characterized in that a fluorocarbon layer is provided between the hole injection layer and the light emitting layer, and the electron transport layer is formed from a phenanthroline compound.

According to a first aspect of the present invention, the electron transport layer is formed from a phenanthroline compound. A phenanthroline compound has a higher energy level of lowest unoccupied molecular orbital (LUMO) than Alq, so that an injection barrier to electrons from the electron injection electrode becomes so small as to be capable of supplying a larger quantity of electrons to the light emitting layer.

A phenanthroline compound is so favorable in electron transporting properties as to be capable of thickening film thickness thereof and preventing a defect from occurring in a film of the electron transport layer.

A derivative of 1,10-phenanthroline having the following structural formula is preferably used as a phenanthroline compound.

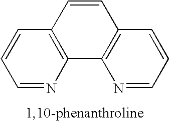

Examples thereof specifically include BCP (2,9-dimethyl-4,7-diphenyl-1,10-phenanthroline) having the following structure.

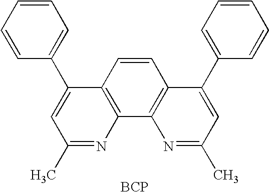

In a first aspect of the present invention, a fluorocarbon layer is provided between the hole injection layer and the light emitting layer. Fluorocarbon can be denoted as CFx, and a thin film thereof can be formed by plasma polymerization of CHF₃. The placement of a fluorenecarbon layer between the hole injection layer and the light emitting layer allows an injection barrier to holes to become so small as to be capable of supplying a larger quantity of holes to the light emitting layer.

According to a first aspect of the present invention, therefore, electrons and holes can be supplied to the light emitting layer in large quantities in balance. Thus, driving voltage can be decreased and luminous efficiency can be raised.

The thickness of a fluorocarbon layer is preferably approximately 5 to 50 Å (0.5 to 5 nm). A thickness out of this range occasionally does not sufficiently bring the effect of a fluorocarbon layer such as to supply a large quantity of holes to the light emitting layer.

The light emitting layer in a first aspect of the present invention is preferably formed from host materials and dopant materials.

According to a first aspect of the present invention, the difference in energy level of lowest unoccupied molecular orbital (LUMO) between the electron transport layer and dopant materials of the light emitting layer adjacent to the electron transport layer can be decreased to 0.2 eV or less to be capable of supplying a large quantity of electrons to the light emitting layer.

In a first aspect of the present invention, a hole transport layer is preferably provided between a fluorocarbon layer and the light emitting layer. Host materials of the light emitting layer adjacent to the hole transport layer are preferably the same compound as hole transporting materials of the hole transport layer. The use of hole transporting materials of the hole transport layer for host materials of the light emitting layer adjacent thereto allows an injection barrier to holes into the light emitting layer to become so small as to be capable of supplying holes to the light emitting layer more efficiently.

Hole transporting materials of the hole transport layer in a first aspect of the present invention are preferably subject to an arylamine compound, particularly preferably a diamine compound.

The hole injection layer in a first aspect of the present invention is preferably formed from metal phthalocyanine. The placement of the hole injection layer formed from metal phthalocyanine allows driving voltage to be restrained from rising on the occasion of continuously driving for a long time.

A second aspect of the present invention is an organic electroluminescent element in which a light emitting layer is disposed between a hole injection electrode and an electron injection electrode, and a hole injection layer is provided between the hole injection electrode and the light emitting layer, and an electron transport layer is provided between the electron injection electrode and the light emitting layer, characterized in that a fluorocarbon layer is provided between the hole injection layer and the light emitting layer, and the electron transport layer is formed from a mixture of a first electron transporting material and a second electron transporting material, and the first electron transporting material is a phenanthroline compound, and the second electron transporting material is a compound having a lower energy level of lowest unoccupied molecular orbital (LUMO) than the first electron transporting material.

According to a second aspect of the present invention, the formation of the electron transport layer from a mixture of the first electron transporting material comprising a phenanthroline compound and the second electron transporting material comprising a compound having a lower energy level of LUMO than the first electron transporting material allows electron injection quantity into the light emitting layer to be controlled and life properties to be improved. The control of electron injection quantity into the light emitting layer restrains electrons from passing through the light emitting layer to the hole transport layer, so that a deterioration in hole transporting materials due to the injection of electrons can be reduced and life properties can be improved.

The content of the second electron transporting material in the electron transport layer is preferably 40 weight % or less, more preferably 30 weight % or less. The content of the first electron transporting material, therefore, is preferably 60 weight % or more, more preferably 70 weight % or more. Too low content of the second electron transporting material occasionally does not sufficiently bring the effect of improving life properties, while too high content of the second electron transporting material brings the possibility of raising driving voltage to decrease luminous efficiency.

A phenanthroline compound to be used as the first electron transporting-material in a second aspect of the present invention is preferably subject to a derivative of 1,10-phenanthroline having the above-mentioned structural formula.

Examples thereof specifically include the above-mentioned BCP.

The second electron transporting material to be used in a second aspect of the present invention is not particularly limited if it has a lower energy level of LUMO than the first electron transporting material and favorable electron transporting properties. In the case of using BCP as the first electron transporting material, the LUMO energy level of BCP is approximately −2.7 eV, so that Alq having an LUMO energy level of approximately −3.0 eV can be used.

In a second aspect of the present invention, a fluorocarbon layer is provided between the hole injection layer and the light emitting layer. Fluorocarbon can be denoted as CFx, and a thin film thereof can be formed by plasma polymerization of CHF₃. The placement of a fluorenecarbon layer between the hole injection layer and the light emitting layer allows an injection barrier to holes to become so small as to be capable of supplying a larger quantity of holes to the light emitting layer.

The thickness of a fluorocarbon layer is preferably approximately 5 to 50 Å (0.5 to 5 nm). A thickness out of this range occasionally does not sufficiently bring the effect of a fluorocarbon layer such as to supply a large quantity of holes to the light emitting layer.

The light emitting layer in a second aspect of the present invention is preferably formed from host materials and dopant materials.

In a second aspect of the present invention, a hole transport layer is preferably provided between a fluorocarbon layer and the light emitting layer. Host materials of the light emitting layer adjacent to the hole transport layer is preferably the same compound as hole transporting materials of the hole transport layer. The use of hole transporting materials of the hole transport layer for host materials of the light emitting layer adjacent thereto allows an injection barrier to holes into the light emitting layer to become so small as to be capable of supplying holes to the light emitting layer more efficiently.

Hole transporting materials of the hole transport layer in a second aspect of the present invention is preferably subject to an arylamine compound, particularly preferably a diamine compound.

The hole injection layer in a second aspect of the present invention is preferably formed from metal phthalocyanine. The placement of the hole injection layer formed from metal phthalocyanine allows driving voltage to be restrained from rising on the occasion of continuously driving for a long time.

A third aspect of the present invention is an organic electroluminescent element in which a light emitting layer is disposed between a hole injection electrode and an electron injection electrode, and a hole injection layer is provided between the hole injection electrode and the light emitting layer, and an electron transport layer is provided between the electron injection electrode and the light emitting layer, characterized in that the hole injection layer is formed from a fluorocarbon layer, and the electron transport layer is formed from a phenanthroline compound or a mixture of a phenanthroline compound and an aluminum complex.

In a third aspect of the present invention, a fluorocarbon layer is provided as the hole injection layer. This fluorocarbon layer can be formed in the same manner as a fluorocarbon layer in a first aspect of the present invention. In a third aspect of the present invention, the electron transport layer is formed from a phenanthroline compound or a mixture of a phenanthroline compound and an aluminum complex. The phenanthroline compound is subject to a phenanthroline compound in a first aspect of the present invention. Examples of an aluminum complex include Alq and Balq. The content of an aluminum complex is preferably 40 weight % or less, more preferably 30 weight % or less. The content of a phenanthroline compound, therefore, is preferably 60 weight % or more, more preferably 70 weight % or more. The mixture with an aluminum complex allows life properties to be improved. Accordingly, too low content of an aluminum complex occasionally does not sufficiently bring the effect of improving life properties, while too high content of an aluminum complex brings the possibility of raising driving voltage to decrease luminous efficiency.

In a third aspect of the present invention, the difference in energy level of lowest unoccupied molecular orbital (LUMO). between the electron transport layer and host materials of the light emitting layer adjacent to the electron transport layer is preferably 0.2 eV or less. Thus, electrons are so easily injected from electron transporting materials into host materials of the light emitting layer as to be capable of sending a large quantity of electrons into the light emitting layer.

The difference in energy level of lowest unoccupied molecular orbital (LUMO) between the electron transport layer and dopant materials of the light emitting layer adjacent to the electron transport layer is preferably 0.2 eV or less. Thus, a large quantity of electrons can be supplied to the light emitting layer.

In a third aspect of the present invention, a hole transport layer is preferably provided between a fluorocarbon layer and the light emitting layer. Hole transporting materials of the hole transport layer is preferably subject to an arylamine derivative, particularly preferably a diamine compound.

Host materials of the light emitting layer adjacent to the hole transport layer is preferably the same compound as hole transporting materials of the hole transport layer. The use of the same compound as host materials of the adjacent light emitting layer as hole transporting materials of the hole transport layer allows an injection barrier to holes into the light emitting layer to become so small as to be capable of supplying holes to the light emitting layer more efficiently.

Matters common to first to third aspects of the present invention are hereinafter described as merely “the present invention”.

In the present invention, the light emitting layer is preferably provided with a plurality thereof laminated. For example, a blue light emitting layer and an orange light emitting layer may be provided and thereby composed as a white luminous element. In this case, the thickness of a fluorocarbon layer and an electron transport layer are adjusted for moving a luminous range between a blue light emitting layer and an orange light emitting layer, so that luminescence from the blue light emitting layer or luminescence from the orange light emitting layer can be intensified. A color tone of luminescence, therefore, can be adjusted.

The light emitting layer in the present invention is preferably formed from host materials and dopant materials as described above. A second dopant material having carrier transporting properties may be contained therein as required. Luminescent dopant materials may be subject to be singlet luminescent materials or triplet luminescent materials (phosphorescent luminescent materials).

Examples of host materials of the light emitting layer are not particularly limited but include a metal-chelated oxynoid compound such as tris(8-quinolinolato)aluminum, diarylbutadiene derivative, stilbene derivative, benzoxazole derivative, benzothiazole derivative, CBP, triazole-based compound, imidazole-based compound, oxadiazole-based compound, condensed ring derivatives such as anthracene, pyrene and perylene, heterocyclic ring derivatives such as pyrazine, naphthyridine, quinoxaline, pyrrolopyridine, pyrimidine, thiophene and thioxanthene, benzoquinolinol metal complex, bipyridine metal complex, rhodamine metal complex, azomethine metal complex, distyryl benzene derivative, tetraphenylbutadiene derivative, stilbene derivative, aldadine derivative, coumarin derivative, phthalimide derivative, naphthalimide derivative, perinone derivative, pyrrolopyrrole derivative, cyclopentadiene derivative, azole derivatives and metal complexes thereof such as imidazole derivative, oxazole derivative, thiazole derivative, oxadiazole derivative, thiadiazole derivative and triazole derivative, benzazole derivatives and metal complexes thereof such as benzoxazole, benzimidazole and benzothiazole, amine derivatives such as triphenylamine derivative and carbazole derivative, merocyanine derivative, porphyrin derivative, a phosphorescent material such as tris(2-phenylpyridine)iridium complex, polymers such as polyphenylene vinylene derivative, poly-para-phenylene derivative, and polythiophane derivative.

Host materials of the light emitting layer are particularly preferably subject to anthracene derivative, aluminum complex, rubrene derivative and arylamine derivative.

Examples of dopant materials of the light emitting layer in the present invention are not particularly limited but include condensed polycyclic aromatic hydrocarbons such as anthracene and perylene, a coumarin derivative such as 7-dimethylamino-4-methylcoumarin, a naphthalimide derivative such as bis(diisopropylphenyl)perylene tetracarboxylic acid imide, perinone derivative, a rare-earth complex such as Eu complex of acetylacetone and benzoylacetone with a ligand of phenanthroline, dicyanomethylenepyran derivative, dicyanomethylenethiopyran derivative, metal phthalocyanine derivatives such as magnesium phthalocyanine and aluminum chlorophthalocyanine, porphyrin derivative, rhodamine derivative, deazaflavin derivative, coumarin derivative, oxazine compound, thioxanthene derivative, cyanine pigment derivative, fluorescein derivative, acridine derivative, quinacridon derivative, pyrrolopyrrole derivative, quinazoline derivative, pyrrolopyridine derivative, squalylium derivative, violanthrone derivative, phenazine derivative, acridone derivative, diazaflavin derivative, pyrromethene derivative and metal complex thereof, phenoxazine derivative, phenoxazone derivative, thiadiazolopyrene derivative, tris(2-phenylpyridine)iridium complex, tris(2-phenylpyridyl)iridium complex, tris[2-(2-thiophenyl)pyridyl]iridium complex, tris[2-(2-benzothiophenyl)pyridyl]iridium complex, tris(2-phenylbenzothiazole)iridium complex, tris(2-phenylbenzoxazole)iridium complex, trisbenzoquinoline iridium complex, bis(2-phenylpyridyl)(acetylacetonate)iridium complex, bis[2-(2-thiophenyl)pyridyl]iridium complex, bis[2-(2-benzothiophenyl)pyridyl](acetylacetonate)iridium complex, and bis(2-phenylbenzothiazole)(acetylacetonate)iridium complex.

According to first and third aspects of the present invention, an amelioration in the balance of electrons and holes in the light emitting layer allows luminous efficiency to be improved.

According to a second aspect of the present invention, a phenanthroline compound is used as a first electron transporting material for the electron transport layer. Thus, driving voltage can be reduced and luminous efficiency can be improved. A second electron transporting material having a relatively low energy level of LUMO is used by mixture or lamination for the electron transport layer, so that life properties can be improved as compared with the case of singly using a phenanthroline compound for the electron transport layer.

### BRIEF DESCRIPTION OF THE DRAWINGS

FIG. 1 is a view showing the relation between driving voltage and luminance in an organic EL element of examples according to a first aspect of the present invention;

FIG. 2 is a view showing the relation between driving time and driving voltage of an organic EL element of examples according to a first aspect of the present invention;

FIG. 3 is a view showing LUMO energy level and HOMO energy level in each layer of an organic EL element of examples according to a first aspect of the present invention;

FIG. 4 is a view showing LUMO energy level and HOMO energy level in each layer of an organic EL element of comparative examples; and

FIG. 5 is a view showing the relation between driving time and luminance of an organic EL element of examples according to first and second aspects of the present invention.

### DETAILED DESCRIPTION OF PREFERRED EMBODIMENTS

The present invention is specifically described hereinafter by examples, and not limited to the following examples.

Examples according to first and third aspects of the present invention are described hereinafter.

### EXAMPLES 1 TO 3 AND COMPARATIVE EXAMPLES 1-1 TO 1-4 AND 2

A hole injection layer, a fluorocarbon layer, a hole transport layer, a light emitting layer 1 (an orange light emitting layer), a light emitting layer 2 (a blue light emitting layer), an electron transport layer and an electron injection electrode (LiF/Al) shown in Table 1 were formed on a glass substrate on which an ITO (indium-tin oxide) film was formed as a hole injection electrode. In Table 1, the numbers in parentheses-denote the thickness (nm) of each of the layers. The fluorocarbon layer was formed by plasma polymerization of CHF₃ gas. Each of the layers except the fluorocarbon layer was formed by vapor deposition process.

With regard to each organic EL element manufactured, chromaticity, electric power efficiency, luminance efficiency and external quantum efficiency were measured to show the results in Table 1. Each organic EL element shown in Table 1 is a white luminous element having an orange light-emitting layer and a blue light emitting layer.

TABLE 1

| | Lumi- | Hole | Fluoro- | Hole | | |
|---|---|---|---|---|---|---|
| | nescent | Injection | carbon | Transport | Luminous | Luminous |
| | Color | Layer | Layer | Layer | Layer 1 | Layer 2 |
| Example 1 | White | CuPC | CFx | NPB | NPB + 3% | TBADN + 2% |
| | | (100) | (10) | (1500) | DBzR | TBP |
| | | | | | (100) | (400) |
| Comparative | White | CuPC | — | NPB | NPB + 3% | TBADN + 2% |
| Example | | (100) | | (1500) | DBzR | TBP |
| 1-1 | | | | | (100) | (400) |
| Comparative | White | CuPC | CFx | NPB | NPB + 3% | TBADN + 2% |
| Example | | (100) | (10) | (1500) | DBzR | TBP |
| 1-2 | | | | | (100) | (400) |
| Comparative | White | CuPC | — | NPB | NPB + 3% | TBADN + 2% |
| Example | | (100) | | (1500) | DBzR | TBP |
| 1-3 | | | | | (100) | (400) |
| Example 2 | White | CuPC | CFx | NPB | CBP + 6% | TBADN + 2% |
| | | (100) | (10) | (1500) | Ir(phq)₃ | TBP |
| | | | | | (100) | (250) |
| Comparative | White | CuPC | CFx | NPB | CBP + 6% | TBADN + 2% |
| Example 2 | | (100) | (10) | (1500) | Ir(phq)₃ | TBP |
| | | | | | (100) | (250) |
| Example 3 | White | CFx | (Hole | NPB | NPB + 3% | TBADN + 2% |
| | | (10) | Injection | (1500) | DBzR | TBP |
| | | | Layer) | | (100) | (400) |

| | | | | | | Electric | Lumi- | External |
|---|---|---|---|---|---|---|---|---|
| | Electron | | | | | Power | nance | Quantum |
| | Transport | | | Chromaticity | | Efficiency | Efficiency | Efficiency |
| | Layer | LiF | Al | CIE(x, y) | | (lm/W) | (cd/A) | (%) |
| Example 1 | BCP | 10 | 2000 | 0.34 | 0.41 | 9.08 | 13.78 | 6.83 |
| | (100) | | | | | | | |
| Comparative | BCP | 10 | 2000 | 0.34 | 0.38 | 3.57 | 8.70 | 5.59 |
| Example | (100) | | | | | | | |
| 1-1 | | | | | | | | |
| Comparative | Alq | 10 | 2000 | 0.35 | 0.39 | 4.62 | 11.05 | 5.45 |
| Example | (100) | | | | | | | |
| 1-2 | | | | | | | | |
| Comparative | Alq | 10 | 2000 | 0.34 | 0.38 | 3.25 | 10.12 | 4.86 |
| Example | (100) | | | | | | | |
| 1-3 | | | | | | | | |
| Example 2 | BCP | 10 | 2000 | 0.33 | 0.39 | 5.96 | 14.82 | 6.72 |
| | (100) | | | | | | | |
| Comparative | Alq | 10 | 2000 | 0.28 | 0.34 | 2.26 | 7.19 | 4.28 |
| Example 2 | (100) | | | | | | | |
| Example 3 | BCP | 10 | 2000 | 0.33 | 0.41 | 9.12 | 13.51 | 6.72 |
| | (100) | | | | | | | |

### EXAMPLES 4 TO 7 AND COMPARATIVE EXAMPLES 3 TO 6

In the same manner as the above-mentioned Examples, each layer shown in Table 2 was formed on a glass substrate, on which an ITO film was formed, to manufacture organic EL elements. With regard to each of the elements, chromaticity, electric power efficiency, luminance efficiency and external quantum efficiency were measured to show the results in Table 2.

TABLE 2

| | | | | | | | | | | | Electric | Lumi- | External |
|---|---|---|---|---|---|---|---|---|---|---|---|---|---|
| | Lumi- | Hole | Fluoro- | Hole | | Electron | | | | | Power | nance | Quantum |
| | nescent | Injection | carbon | Transport | Luminous | Transport | | | Chromaticity | | Efficiency | Efficiency | Efficiency |
| | color | Layer | Layer | Layer | Layer | Layer | LiF | Al | CIE (x, y) | | (lm/W) | (cd/A) | (%) |
| Example 4 | Blue | CuPC | CFx | NPB | TBADN + 2% | BCP | 10 | 2000 | 0.17 | 0.38 | 12.69 | 17.23 | 9.24 |
| | | (100) | (10) | (1500) | TBP | (100) | | | | | | | |
| | | | | | (400) | | | | | | | | |
| Comparative | Blue | CuPC | CFx | NPB | TBADN + 2% | Alq | 10 | 2000 | 0.19 | 0.40 | 5.97 | 11.90 | 6.11 |
| Example 3 | | (100) | (10) | (1500) | TBP | (100) | | | | | | | |
| | | | | | (400) | | | | | | | | |
| Example 5 | Orange | CuPC | CFx | NPB | NPB + 3% | BCP | 10 | 2000 | 0.47 | 0.46 | 8.88 | 12.40 | 5.58 |
| | | (100) | (10) | (1500) | DBzR | (100) | | | | | | | |
| | | | | | (400) | | | | | | | | |
| Comparative | Orange | CuPC | CFx | NPB | NPB + 3% | Alq | 10 | 2000 | 0.45 | 0.48 | 2.42 | 6.16 | 2.40 |
| Example 4 | | (100) | (10) | (1500) | DBzR | (100) | | | | | | | |
| | | | | | (400) | | | | | | | | |
| Example 6 | Green | CuPC | CFx | NPB | NPB + | BCP | 10 | 2000 | 0.26 | 0.64 | 8.25 | 11.53 | 4.13 |
| | | (100) | (10) | (1500) | tBuDPN (400) | (100) | | | | | | | |
| Comparative | Green | CuPC | CFx | NPB | NPB + | Alq | 10 | 2000 | 0.27 | 0.64 | 3.13 | 7.21 | 3.21 |
| Example 5 | | (100) | (10) | (1500) | tBuDPN (400) | (100) | | | | | | | |
| Example 7 | Red | CuPC | CFx | NPB | Alq + 3% | BCP | 10 | 2000 | 0.62 | 0.37 | 0.60 | 1.63 | 0.58 |
| | | (100) | (10) | (1500) | DCJTB | (100) | | | | | | | |
| | | | | | (400) | | | | | | | | |
| Comparative | Red | CuPC | CFx | NPB | Alq + 3% | Alq | 10 | 2000 | 0.62 | 0.37 | 0.33 | 1.13 | 0.43 |
| Example 6 | | (100) | (10) | (1500) | DCJTB | (100) | | | | | | | |
| | | | | | (400) | | | | | | | | |

Thin film-forming materials used in each of the above-mentioned Examples and Comparative Examples are hereinafter described.

Alq is tris-(8-quinolinate)aluminum(III) and has the following structure.

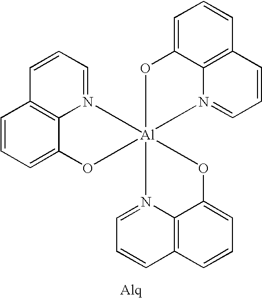

NPB is N,N′-di(naphthacene-1-yl)-N,N′-diphenylbenzidine and has the following structure.

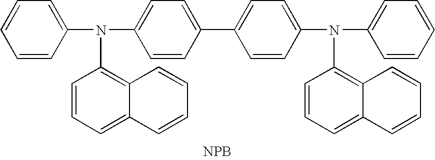

DBZR is 5,12-bis{4-(6-methylbenzothiazole-2-yl)phenyl}-6,11-diphenylnaphthacene and has the following structure.

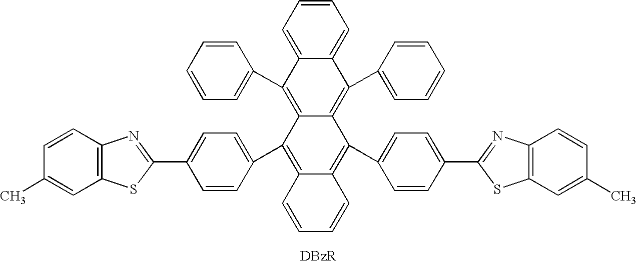

tBuDPN is 5,12-bis(4-tert-butylphenyl)naphthacene and has the following structure.

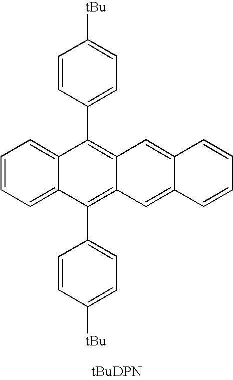

CBP is 4,4′-N,N′-dicarbazole-biphenyl and has the following structure.

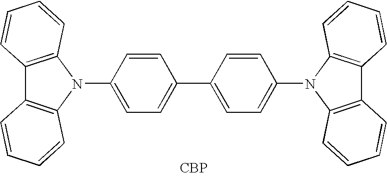

Ir(phq)₃ is tris(2-phenylquinoline)iridium(III) and has the following structure.

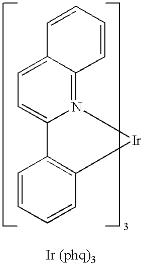

TBADN is 2-tert-butyl-9,10-di(2-naphthyl)anthracene and has the following structure.

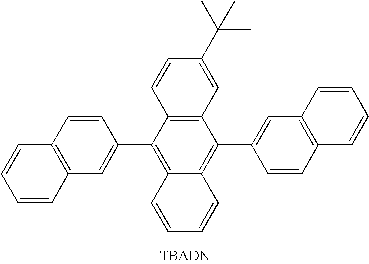

TBP is 2,5,8,11-tetra-tert-butylperylene and has the following structure.

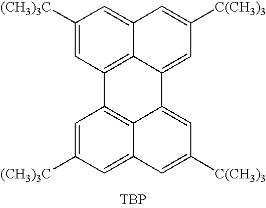

DCJTB is (4-dicyanomethylene)-2-tert-butyl-6-(1,1,7,7-tetramethyljulolidyl-9-enyl)-4H-pyran and has the following structure.

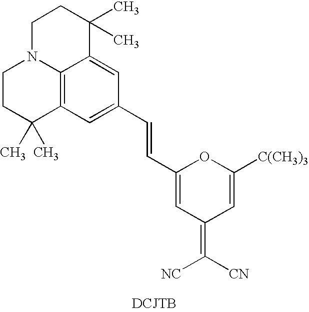

Balq mentioned in the above as an example of aluminum complex is bis(2-methyl-8-quinolinolato)-4-phenylphenolate aluminum(III) and has the following structure.

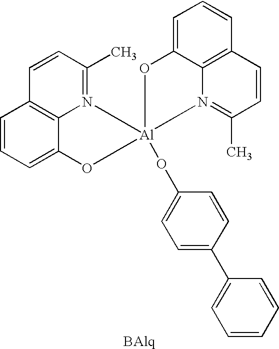

As clarified from the results shown in Tables 1 and 2, with regard to an organic EL element of examples according to the present invention, electric power efficiency, luminance efficiency and external quantum efficiency are raised, and luminous efficiency is improved as compared with an organic EL element of comparative examples. Example 3 is an example according to a third aspect of the present invention. The other examples are examples according to a first aspect of the present invention.

FIG. 1 is a view showing the relation between driving voltage and luminance of Example 1 and Comparative Example 1-1. As clarified from FIG. 1, a high luminance is obtained at a low driving voltage in an organic EL element of Example 1 according to a first aspect of the present invention.

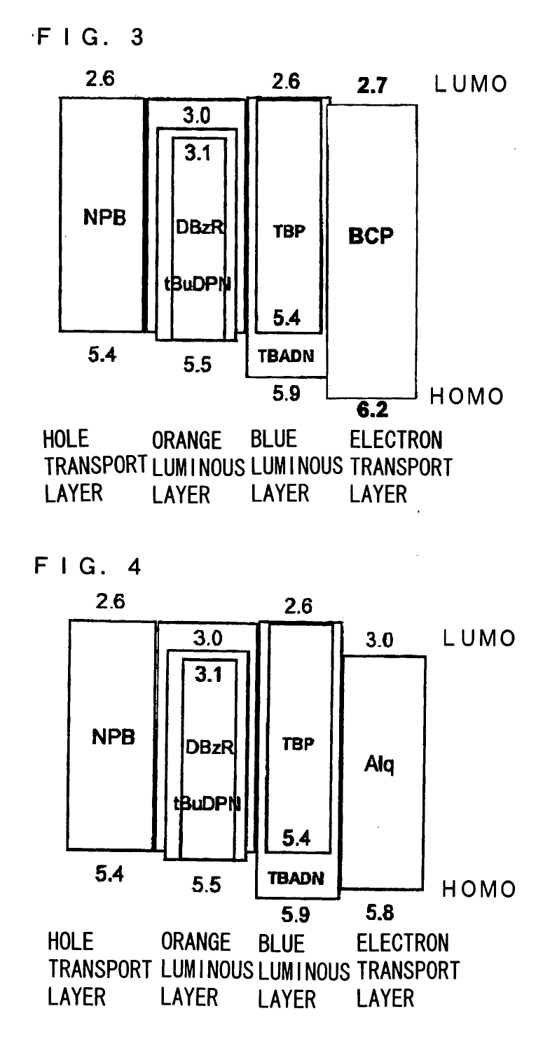

FIG. 3 is a view schematically showing LUMO energy level and HOMO energy level in each layer of an organic EL element of examples according to a first aspect of the present invention. FIG. 4 is a view schematically showing LUMO energy level and HOMO energy level in each layer of an organic EL element of comparative examples. As clarified from FIGS. 3 and 4, the use of BCP as materials of an electron transport layer according to a first aspect of the present invention allows the difference in energy level of LUMO from a light emitting layer adjacent thereto to be 0.1 eV. Thus, as compared with the conventional case of using Alq for an electron transport layer, a large quantity of electrons can be supplied to a light emitting layer to be capable of reducing driving voltage and improving luminous efficiency.

In an organic EL element having two light emitting layers of an orange light emitting layer and a blue light emitting layer shown in FIG. 3, the replacement of Alq with BCP in materials of an electron transport layer allows a luminous range of the recombination of holes and electrons to be pushed into the side of an orange light emitting layer. As a result, luminescence of orange color can be intensified and a color tone of luminescence can be controlled.

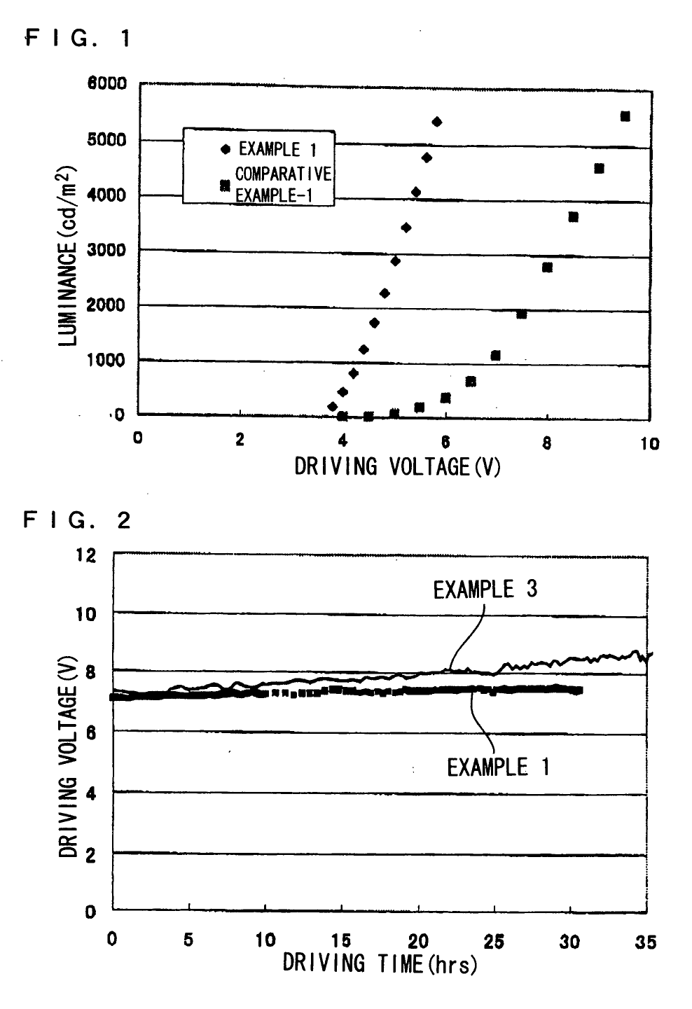

FIG. 2 is a view showing the relation between driving time and driving voltage in Example 1 and Example 3. With regard to Example 3, a hole injection layer comprising CuPC (copper phthalocyanine) is not provided but a fluorocarbon layer is directly provided on a hole injection electrode. As clarified from the results shown in FIG. 2, in Example 3 in which a hole injection layer comprising CuPC is not provided, driving time is prolonged and driving voltage is raised. On the contrary, in Example 1 in which a hole injection layer comprising CuPC is provided, such a rise in driving voltage is restrained.

Examples according to a second aspect of the present invention are hereinafter described.

### EXAMPLES 8 AND 9

A hole injection layer, a fluorocarbon layer, a hole transport layer, a light emitting layer 1 (an orange light emitting layer), a light emitting layer 2 (a blue light emitting layer), an electron transport layer and an electron injection electrode (LiF/Al) shown in Table 3 were formed on a glass substrate on which an ITO (indium-tin oxide) film was formed as a hole injection electrode. In Table 3, the numbers in parentheses denote the thickness (nm) of each of the layers. The fluorocarbon layer was formed by plasma polymerization of CHF₃ gas. Each of the layers except the fluorocarbon layer was formed by vapor deposition process. In Table 3, the numerical values of LiF and Al denote the thickness of the layers. % in the light emitting layer and the electron transport layer denotes weight %.

With regard to each organic EL element manufactured, chromaticity, electric power efficiency, luminance efficiency, external quantum efficiency and luminance half-value time were measured to show the results in Table 3. Each organic EL element shown in Table 3 is a white luminous element having an orange light emitting layer and a blue light emitting layer. Examples 1 and 2 and Comparative Example 1-2 are shown together in Table 3.

TABLE 3

| | | Hole | Fluoro- | Hole | | | Electron |
|---|---|---|---|---|---|---|---|
| | Luminescent | Injection | carbon | Transport | Luminous | Luminous | Transport |
| | Color | Layer | Layer | Layer | Layer 1 | Layer 2 | Layer |
| Example 8 | White | CuPC | CFx | NPB | NPB + 3% | TBADN + 2% | BCP + 20% |
| | | (100) | (10) | (1500) | DBzR | TBP | Alq |
| | | | | | (100) | (400) | (100) |
| Example 1 | White | CuPC | CFx | NPB | NPB + 3% | TBADN + 2% | BCP |
| | | (100) | (10) | (1500) | DBzR | TBP | (100) |
| | | | | | (100) | (400) | |
| Comparative | White | CuPC | CFx | NPB | NPB + 3% | TBADN + 2% | Alq |
| Example | | (100) | (10) | (1500) | DBzR | TBP | (100) |
| 1-2 | | | | | (100) | (400) | |
| Example 9 | White | CuPC | CFx | NPB | CBP + 6% | TBADN + 2% | BCP + 20% |
| | | (100) | (10) | (1500) | Ir(phq)₃ | TBP | Alq |
| | | | | | (100) | (400) | (100) |
| Example 2 | White | CuPC | CFx | NPB | CBP + 6% | TBADN + 2% | BCP |
| | | (100) | (10) | (1500) | Ir(phq)₃ | TBP | (100) |
| | | | | | (100) | (400) | |

| | | | | | Electric | | External | Luminance |
|---|---|---|---|---|---|---|---|---|
| | | | | | Power | Luminance | Quantum | Half-Value |
| | | | Chromaticity | | Efficiency | Efficiency | Efficiency | Time |
| | LiF | Al | CIE(x, y) | | (lm/W) | (cd/A) | (%) | (hrs) |
| Example 8 | 10 | 2000 | 0.34 | 0.41 | 7.58 | 13.62 | 6.55 | 1150 |
| Example 1 | 10 | 2000 | 0.34 | 0.41 | 9.08 | 13.78 | 6.83 | 784 |
| Comparative | 10 | 2000 | 0.35 | 0.39 | 4.62 | 11.05 | 5.45 | 3025 |
| Example | | | | | | | | |
| 1-2 | | | | | | | | |
| Example 9 | 10 | 2000 | 0.31 | 0.39 | 5.47 | 13.02 | 7.76 | 4050 |
| Example 2 | 10 | 2000 | 0.33 | 0.39 | 5.96 | 14.82 | 8.16 | 3500 |

### EXAMPLES 10 TO 13

In the same manner as the above-mentioned Examples, each layer shown in Table 4 was formed on a glass substrate, on which an ITO film was formed, to manufacture organic EL elements. With regard to each of the elements, chromaticity, electric power efficiency, luminance efficiency, external quantum efficiency and luminance half-value time were measured to show the results in Table 4. Examples 4 to 7 are shown together in Table 4.

TABLE 4

| | | Hole | Fluoro- | Hole | | Electron |
|---|---|---|---|---|---|---|
| | Luminescent | Injection | carbon | Transport | Luminous | Transport |
| | Color | Layer | Layer | Layer | Layer | Layer |
| Example | Blue | CuPC | CFx | NPB | TBADN + 2% | BCP + 20% |
| 10 | | (100) | (10) | (1500) | TBP | Alq |
| | | | | | (400) | (100) |
| Example 4 | Blue | CuPC | CFx | NPB | TBADN + 2% | BCP |
| | | (100) | (10) | (1500) | TBP | (100) |
| | | | | | (400) | |
| Example | Orange | CuPC | CFx | NPB | NPB + 3% | BCP + 20% |
| 11 | | (100) | (10) | (1500) | DBzR | Alq |
| | | | | | (400) | (100) |
| Example 5 | Orange | CuPC | CFx | NPB | NPB + 3% | BCP |
| | | (100) | (10) | (1500) | DBzR | (100) |
| | | | | | (400) | |
| Example | Green | CuPC | CFx | NPB | NPB + tBUDPN | BCP + 20% |
| 12 | | (100) | (10) | (1500) | (400) | Alq |
| | | | | | | (100) |
| Example 6 | Green | CuPC | CFx | NPB | NPB + tBuDPN | BCP |
| | | (100) | (10) | (1500) | (400) | (100) |
| Example | Red | CuPC | CFx | NPB | Alq + 3% | BCP + 20% |
| 13 | | (100) | (10) | (1500) | DCJTB | Alq |
| | | | | | (400) | (100) |
| Example 7 | Red | CuPC | CFx | NPB | Alq + 3% | BCP |
| | | (100) | (10) | (1500) | DCJTB | (100) |
| | | | | | (400) | |

| | | | | | | | | Luminance |
|---|---|---|---|---|---|---|---|---|
| | | | | | Electric | | External | Half- |
| | | | | | Power | Luminance | Quantum | Value |
| | | | Chromaticity | | Efficiency | Efficiency | Efficiency | Time |
| | LiF | Al | CIE(x, y) | | (lm/W) | (cd/A) | (%) | (hrs) |
| Example | 10 | 2000 | 0.17 | 0.30 | 5.95 | 10.59 | 7.03 | 1025 |
| 10 | | | | | | | | |
| Example 4 | 10 | 2000 | 0.17 | 0.36 | 12.69 | 17.23 | 9.24 | 329 |
| Example | 10 | 2000 | 0.48 | 0.46 | 6.20 | 9.90 | 4.68 | 4000 |
| 11 | | | | | | | | |
| Example 5 | 10 | 2000 | 0.47 | 0.46 | 8.88 | 12.40 | 5.58 | 3600 |
| Example | 10 | 2000 | 0.26 | 0.64 | 5.74 | 9.45 | 3.78 | 3400 |
| 12 | | | | | | | | |
| Example 6 | 10 | 2000 | 0.26 | 0.64 | 8.25 | 11.53 | 4.13 | 2700 |
| Example | 10 | 2000 | 0.63 | 0.37 | 0.58 | 1.58 | 0.56 | 1800 |
| 13 | | | | | | | | |
| Example 7 | 10 | 2000 | 0.62 | 0.37 | 0.60 | 1.63 | 0.58 | 1580 |

As clarified from the results shown in Tables 3 and 4, with regard to an organic EL element of Examples 8 and 13 according to a second aspect of the present invention, it is found that luminance half-value time is prolonged and life properties are improved as compared with an organic EL element of Examples 1, 2 and 4 to 7 in which BCP was singly used for an electron'transport layer.

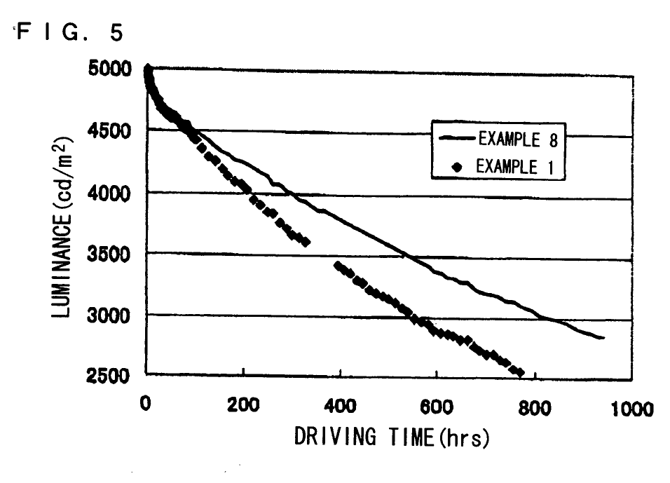

FIG. 5 is a view showing the relation between driving time and luminance of an organic EL element of Example 8 and Example 1. As clarified also from FIG. 5, with regard to Example 8 according to the present invention, it is found that a high luminance is obtained even in driving for a long time and life properties are superior as compared with Example 1.

What is claimed is:

1. An organic electroluminescent element comprising;
a hole injection electrode;
an electron injection electrode;
a light emitting layer disposed between the hole injection electrode and the electron injection electrode;
a hole injection layer provided between the hole injection electrode and the light emitting layer; and
an electron transport layer provided between the electron injection electrode and the light emitting layer;
wherein a fluorocarbon layer is provided between the hole injection layer and the light emitting layer and wherein the electron transport layer is formed from a phenanthroline compound.

2. The organic electroluminescent element according to claim 1, wherein the light emitting layer is formed from a host material and a dopant material.

3. The organic electroluminescent element according to claim 2, wherein a difference in energy level of lowest unoccupied molecular orbital (LUMO) between the electron transport layer and the dopant material of the light emitting layer adjacent to the electron transport layer is 0.2 eV or less.

4. The organic electroluminescent element according to claim 1, wherein a hole transport layer is provided between the fluorocarbon layer and the light emitting layer.

5. The organic electroluminescent element according to claim 4, wherein a host material of the light emitting layer adjacent to the hole transport layer is the same compound as a hole transporting material of the hole transport layer.

6. The organic electroluminescent element according to claim 4, wherein the hole transporting material of the hole transport layer is an arylamine compound.

7. The organic electroluminescent element according to claim 1, wherein the hole injection layer is formed from a metal phthalocyanine compound.

8. The organic electroluminescent element according to claim 1, wherein the light emitting layer is provided with a plurality thereof laminated.

9. The organic electroluminescent element according to claim 1, being a white light emitting element wherein a blue light emitting layer and an orange light emitting layer are provided as the light emitting layer.

10. The organic electroluminescent element according to claim 2, wherein a phosphorescent luminescent material is contained as the dopant material.

11. An organic electroluminescent element comprising;
a hole injection electrode;
an electron injection electrode;
a light emitting layer disposed between the hole injection electrode and the electron injection electrode;
a hole injection layer provided between the hole injection electrode and the light emitting layer; and
an electron transport layer provided between the electron injection electrode and the light emitting layer;
wherein a fluorocarbon layer is provided between the hole injection layer and the light emitting layer and wherein the electron transport layer is formed from a mixture of a first electron transporting material and a second electron transporting material, the first electron transporting material being a phenanthroline compound, and the second electron transporting material being a compound having a lower energy level of lowest unoccupied molecular orbital (LUMO) than the first electron transporting material.

12. The organic electroluminescent element according to claim 11, wherein the light emitting layer is formed from a host material and a dopant material.

13. The organic electroluminescent element according to claim 11, wherein the electron transport layer contains 70 weight % or more of the first electron transporting material and 30 weight % or less of the second electron transporting material.

14. The organic electroluminescent element according to claim 11, wherein a hole transport layer is provided between the fluorocarbon layer and the light emitting layer.

15. The organic electroluminescent element according to claim 14, wherein a host material of the light emitting layer adjacent to the hole transport layer is the same compound as a hole transporting material of the hole transport layer.

16. The organic electroluminescent element according to claim 14, wherein a hole transporting material of the hole transport layer is an arylamine compound.

17. The organic electroluminescent element according to claim 11, wherein the hole injection layer is formed from a metal phthalocyanine compound.

18. The organic electroluminescent element according to claim 11, wherein the light emitting layer is provided with a plurality thereof laminated.

19. The organic electroluminescent element according to claim 11, being a white light emitting element wherein a blue light emitting layer and an orange light emitting layer are provided as the light emitting layer.

20. The organic electroluminescent element according to claim 12, wherein a phosphorescent luminescent material is contained as the dopant material.

21. An organic electroluminescent element comprising;
a hole injection electrode;
an electron injection electrode;
a light emitting layer disposed between the hole injection electrode and the electron injection electrode;
a hole injection layer provided between the hole injection electrode and the light emitting layer; and
an electron transport layer provided between the electron injection electrode and the light emitting layer;
wherein the hole injection layer is formed from a fluorocarbon layer and wherein the electron transport layer is formed from a phenanthroline compound or a mixture of a phenanthroline compound and an aluminum complex.

22. The organic electroluminescent element according to claim 21, wherein the light emitting layer is formed from a host material and a dopant material.

23. The organic electroluminescent element according to claim 21, wherein the light emitting layer is composed of only one layer.

24. The organic electroluminescent element according to claim 21, wherein the light emitting layer is composed of two layers or three layers different in luminescent color.

25. The organic electroluminescent element according to claim 22, wherein a difference in energy level of lowest unoccupied molecular orbital (LUMO) between the electron transport layer and the host material of the light emitting layer adjacent to the electron transport layer is 0.2 eV or less.

26. The organic electroluminescent element according to claim 22, wherein the host material of the light emitting layer is formed from anthracene derivative, aluminum complex, rubrene derivative or arylamine derivative.

27. The organic electroluminescent element according to claim 22, wherein a difference in energy level of lowest unoccupied molecular orbital (LUMO) between the electron transport layer and the dopant material of the light emitting layer adjacent to the electron transport layer is 0.2 eV or less.

28. The organic electroluminescent element according to claim 21, wherein a hole transport layer is provided between the fluorocarbon layer and the light emitting layer.

29. The organic electroluminescent element according to claim 28, wherein a host material of the light emitting layer adjacent to the hole transport layer is the same compound as a hole transporting material of the hole transport layer.

30. The organic electroluminescent element according to claim 28, wherein the hole transporting material of the hole transport layer is an arylamine derivative.

31. The organic electroluminescent element according to claim 24, being a white light emitting element wherein a blue light emitting layer and an orange light emitting layer are provided as the light emitting layer.

32. The organic electroluminescent element according to claim 22, wherein a phosphorescent luminescent material is contained as the dopant material.
